(19) United States
(12) Patent Application Publication
(10) Pub. No.: US 2025/0065341 A1
(43) Pub. Date: Feb. 27, 2025

(54) METHOD FOR RECYCLING SILICON PHOTOVOLTAIC MODULES

(71) Applicants: NEWSOUTH INNOVATIONS PTY LIMITED, Sydney, New South Wales (AU); UNIVERSIDADE FEDERAL DO RIO GRANDE DO SUL (UFRGS), Porto Alegre (BR)

(72) Inventors: Pablo Ribeiro DIAS, Sydney, New South Wales (AU); Lucas Margarezzi SCHMIDT, Porto Alegre (BR); Hugo Marcelo VEIT, Porto Alegre (BR)

(21) Appl. No.: 18/723,104

(22) PCT Filed: Dec. 20, 2022
(86) PCT No.: PCT/AU2022/051545

§ 371 Date: Jun. 21, 2024

(30) Foreign Application Priority Data
Dec. 21, 2021 (AU) 2021904167

(51) Int. Cl. B03C 7/06; B02C 23/14; B03C 7/00; H01L 31/18

(52) U.S. Cl. CPC B03C 7/06; B02C 23/14; B03C 7/003; H01L 31/18

(57) ABSTRACT

A method for recovering metallic materials from crystalline silicon photovoltaic modules. The method includes removing aluminium frames and junction boxes from the photovoltaic modules to provide photovoltaic sandwich structures. The method further includes shredding the photovoltaic sandwich structures to form photovoltaic sandwich structure particles and electrostatically separating the photovoltaic sandwich structure particles into a first fraction and a second fraction with an electrostatic separator. The method further includes feeding at least a portion of the second fraction to an electrostatic separator for one or more subsequent electrostatic separations into the first and second fractions, wherein the first fraction includes less than 5 percent by weight of total polymer particles and is substantially free of glass particles.

### TECHNICAL FIELD

The present disclosure relates to a method and apparatus for recycling photovoltaic modules, and in particular to separating and recovering component materials from crystalline silicon photovoltaic modules.

### BACKGROUND

With a continued worldwide focus on renewable energy sources, global installed photovoltaics are anticipated to rise 11-fold in the next 30 years. This increased usage of photovoltaics necessarily leads to an increase in photovoltaic waste as the modules reach their end of life, with crystalline silicon photovoltaic modules expected to make up the majority of photovoltaic module waste for the foreseeable future.

Crystalline silicon photovoltaic modules typically comprise: glass, aluminum frames, EVA (ethylene-vinyl acetate) copolymer transparent encapsulating layers, solar cells, junction boxes (j-box), polymer backsheet and other accessories such as cabling. A typical cross-section of these modules, with several layers of distinct materials, is shown in FIG. 1.

Photovoltaic modules typically have a lifespan of 25-30 years, although the initiation of photovoltaic end of life is contingent on the module's performance and can occur sooner for a number of reasons. For example, if modules are defective or significantly degraded and repair is not feasible, then end of life may occur many years prior to the module's expected lifetime.

A benefit of photovoltaic recycling arises from the re-use potential of recovered materials, which can offset the economic costs and environmental impacts of raw material production. In addition, crystalline silicon panels contain a number of valuable metals such as aluminum, copper and silver, which have finite reserves and that may become depleted in the future.

The recycling of crystalline silicon photovoltaic modules is technically viable, and while the environmental benefits are clear it is often not economically feasible due to high equipment and processing costs, difficulties in achieving adequate separation, and either insufficient recovery of valuable components or the valuable component fraction being insufficiently pure that do not justify the investment and operating costs. In addition, known recycling techniques, while achieving a separation of components, can involve hazardous chemicals or require high energy consumption and therefore the environmental benefits of recycling the photovoltaic modules are outweighed by the environmental costs of performing the recycling. In some methods, separation is achieved however the resulting recovered materials are not in suitable form for re-use. Often, waste photovoltaic modules are simply disposed of as landfill.

There are several approaches to recycling photovoltaic modules. Typically, such methods have an initial step of mechanically separating the frame and junction box (j-box) from the photovoltaic sandwich structure. In crystalline modules, this sandwich structure is made up of solar cells that are sandwiched between layers of an ethylene-vinyl acetate (EVA) encapsulant which adheres the cells to the front glass and polymer backsheet.

Existing methods then often look to separate the layers of the photovoltaic sandwich structure. These layers can be separated, for example, using thermal or chemical techniques which target the EVA. Thermal treatments involve decomposing the EVA layer at high temperatures of approximately 500° C. using either pyrolysis or combustion. This allows for separation of glass and solar cells. However, achieving the high temperatures required for thermal separation can be energy-intensive and mechanical pressure from decomposing gases can cause the glass layer and/or solar cells to crack, thereby reducing the value of the materials compared to the recovery of whole material layers.

Separation of the front glass, solar cell and backsheet can also be achieved using chemical solvents to dissolve the encapsulant. Once separated, the solar cells can be treated with specific acids or hydroxides to individually remove internal metals such as copper and silver. Chemical recycling techniques have the potential to separate high-quality metals, however they often require the use of toxic chemicals which must be appropriately disposed of after a single use, thereby negatively impacting the environment.

The European “Full Recovery End of Life Photovoltaic” (FRELP) project is a targeted recovery process for crystalline modules, able to achieve high-quality material yields using a multi-stepped approach. After removal of the aluminum frame, j-box and cabling, glass is separated the resulting photovoltaic sandwich structure using a high-frequency cutting knife with an elevated temperature furnace. Optical separation is then used to separate glass into similarly sized pieces and remove contaminants. The remaining laminate is cut into small pieces and incinerated to produce energy and ash containing silicon and various metals and the ash sieved to separate aluminum connectors originally contained in the laminate. Acid leaching is used to dissolve metals and the remaining residue can be filtered to recover the silicon fraction and electrolysis used to yield the copper and silicon from the metallic oxides within the remaining solution.

The FRELP process provides a good recovery of material, allowing for over 95% of the glass, aluminum, silver and silicon to be recovered. However, the FRELP process requires a high throughput of at least approximately 7,000 tonnes/year to be economically viable, with reductions in the quantities of valuable materials (such as silver and silicon) used in newer modules posing a further economic challenge for the FRELP and other processes. Further, the FRELP process requires a time intensive multi-stepped approach and does not separate the glass and silicon cell components as whole layers, thereby reducing the value of the recovered materials. The separation step of the FRELP process also

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY

According to one aspect, the present disclosure provides a method for recovering metallic materials from crystalline silicon photovoltaic modules, the method comprising:
removing aluminum frames and junction boxes from the photovoltaic modules to provide photovoltaic sandwich structures;
shredding the photovoltaic sandwich structures to form photovoltaic sandwich structure particles, the photovoltaic sandwich structure particles comprising: metallic particles, silicon particles, glass particles and polymer particles;
electrostatically separating the photovoltaic sandwich structure particles into a first fraction and a second fraction with an electrostatic separator, the electrostatic separator comprising:
   a grounded rotating roll electrode rotating at a roll rotation speed about a substantially horizontal longitudinal roll electrode axis;
   a corona electrode and an electrostatic electrode, wherein a difference in electric potential between the corona and electrostatic electrodes and the roll electrode define an electric potential difference of the electrostatic separator;
   a splitter sized, positioned and angled for splitting the first and second fractions;
   a surface brush for dislodging second fraction particles from the surface of the grounded rotating roll electrode;
   a humidity sensor for measuring humidity, wherein electrostatically separating the photovoltaic sandwich structure particles is conducted at a humidity of less than about 60%; and
feeding at least a portion of the second fraction to an electrostatic separator for one or more subsequent electrostatic separations into the first and second fractions;
wherein the roll rotation speed of the grounded rotating roll electrode, the electric potential difference and the splitter size, position are angle are selected such that the first fraction comprises less than 5 percent by weight of total polymer particles and is substantially free of glass particles.

Shredding of the photovoltaic sandwich structures may be conducted to provide a desired particle size, and optionally a desired particle size distribution, of the photovoltaic sandwich particles for electrostatic separation.

In some embodiments, shredding the photovoltaic sandwich structures comprises sieving the photovoltaic sandwich structure particles thereby to define a maximum particle size of the photovoltaic sandwich particles for electrostatic separation.

Particles too large to pass through the sieve can continue to undergo shredding until the particle size is sufficiently reduced to pass through the sieve. Sieving may also be utilised to define a minimum particle size of the photovoltaic sandwich structure for electrostatic separation. For example, it may be desirable in some embodiments to remove fines or dust particles prior to the electrostatic separation process.

The maximum particle size may be less than 20 mm, less than 10 mm, less than 9 mm, less than 8 mm, less than 7 mm, less than 6 mm, less than 5 mm, less than 4mm, less than 3 mm, less than 2 mm, or less than 1 mm. The minimum particle size may be more than 0.1 mm, more than 1 mm, more than 2 mm, more than 3 mm, more than 5 mm, more than 6 mm, more than 7 mm, more than 8 mm, more than 9 mm or more than 10 mm. The particle size may be in a range from any one of the described lower values to any one of the upper values.

In some embodiments, it may be desirable to have particles substantially homogenously sized undergoing electrostatic separation. For example, the minimum and maximum particle size may be defined as being within a certain percentage of the average particle size, such as ±25%, or ±10%, or less.

In some embodiments, one or more of the subsequent electrostatic separations are performed by one or more additional electrostatic separators in series. In such an embodiment, at least a portion of the second fraction from a first electrostatic separator is fed to a second electrostatic separator for separating into further first and second fractions. Where more than one electrostatic separator is used in the method of the present disclosure, the operating parameters such as the roll rotation speed of the grounded rotating roll electrode, the electric potential difference and the splitter size, position are angle may be the same for all electrostatic separators in the series.

In some embodiments, one or more of the subsequent electrostatic separations are performed by an electrostatic separator that performed one or more preceding separations. In such an embodiment, at least a portion of the second fraction from an electrostatic separator is recycled to form part of the feed for the same electrostatic in which the initial separation occurred. It will be appreciated that a combination of electrostatic separators in series and recycling of the second fraction could be employed in a method according to the present disclosure.

The number of subsequent electrostatic separations is not particularly limited an may be, for example, 1, 2, 3, 4, 5, or more subsequent electrostatic separations.

In some embodiments, the roll rotation speed of the grounded rotating roll electrode is about 30 rpm.

In some embodiments, the electric potential difference of the electrostatic separator is about 25 kV.

In some embodiments, the splitter is at about a 10° angle to the vertical.

Methods according to the present disclosure are directed to separating the higher value metal components from the glass and polymer components present in crystalline silicon photovoltaic modules, and in particular to achieve a first fraction that has a high recovery of the metal components with relatively little polymer or glass components. In a particularly preferred embodiment, the first fraction is substantially free of polymer particles.

The metal particles may comprise silver particles, copper particles, and aluminum particles.

The first fraction further comprises at least a portion of the silicon particles. For example, the first fraction comprises at least 50 percent by weight of total silicon particles, or at least 55 percent by weight of total silicon particles, or at least 60 per cent by weight of total silicon particles, or at least 65 percent by weight of total silicon particles, or more.

In some embodiments, the roll rotation speed of the grounded rotating roll electrode, the electric potential difference and the splitter size, position are angle are selected such that the first fraction comprises greater than 90 percent by weight of total silver particles.

In some embodiments, the roll rotation speed of the grounded rotating roll electrode, the electric potential difference and the splitter size, position are angle are selected such that the first fraction comprises greater than 95 percent by weight of total silver particles.

In some embodiments, the roll rotation speed of the grounded rotating roll electrode, the electric potential difference and the splitter size, position are angle are selected such that the first fraction comprises greater than 70 percent by weight of total aluminum particles.

The method is conducted at less than 60% humidity, as measured by the humidity sensor. For example, the method may be conducted at less than 55% humidity, at less than 50% humidity, at less than 45% humidity, at less than 40% humidity, or lower. Where the humidity approaches or exceeds a predetermined threshold value such as those outlined above, the method may further comprise steps for reducing humidity with a heater and/or a dehumidifier.

In some embodiments, the method further comprises feeding a monolayer of the photovoltaic sandwich structure particles to the electrostatic separator. The monolayer may formed with a vibratory feeder. The vibratory feeder may be operated to control the feed rate and spacing of the particles in the monolayer of the photovoltaic sandwich structure particles that are fed to the electrostatic separator.

According to another aspect, the present disclosure provides a method for recovering metallic materials from crystalline silicon photovoltaic modules, the method comprising:
removing aluminum frames and junction boxes from the photovoltaic modules to provide photovoltaic sandwich structures;
shredding the photovoltaic sandwich structures to form photovoltaic sandwich structure particles, the photovoltaic sandwich structure particles comprising: metallic particles, silicon particles, glass particles and polymer particles;
sieving the photovoltaic sandwich structure particles to provide feed photovoltaic sandwich structure particles having a predefined maximum particle size;
feeding a monolayer of the feed photovoltaic sandwich structure particles to an electrostatic separator, and electrostatically separating the photovoltaic sandwich structure particles into a first fraction and a second fraction with the electrostatic separator, the electrostatic separator comprising:
   a grounded rotating roll electrode rotating at about 30 rpm about a substantially horizontal longitudinal roll electrode axis;
   a corona electrode and an electrostatic electrode, wherein a difference in electric potential between the corona and electrostatic electrodes and the roll electrode define an electric potential difference of the electrostatic separator of about 25 kV;
   a splitter sized, positioned and angled for splitting the first and second fractions;
   a surface brush for dislodging second fraction particles from the surface of the grounded rotating roll electrode;
   a humidity sensor for measuring humidity, wherein electrostatically separating the photovoltaic sandwich structure particles is conducted at a humidity of less than about 60%; and
feeding at least a portion of the second fraction to an electrostatic separator for one or more subsequent electrostatic separations into the first and second fractions;
wherein the first fraction comprises less than 5 percent by weight of total polymer particles and is substantially free of glass particles.

Other aspects and embodiments relating to the present disclosure are described herein. It will be appreciated that each example, aspect and embodiment of the present disclosure described herein is to be applied mutatis mutandis to each and every other example, aspect or embodiment unless specifically stated otherwise. The present disclosure is not to be limited in scope by the specific examples described herein, which are intended for the purpose of exemplification only. Functionally-equivalent products, compositions and processes are clearly within the scope of the disclosure as described herein.

### Definitions

With regards to the definitions provided herein, unless stated otherwise, or implicit from context, the defined terms and phrases include the provided meanings. Unless explicitly stated otherwise, or apparent from context, the terms and phrases below do not exclude the meaning that the term or phrase has acquired by a person skilled in the relevant art. The definitions are provided to aid in describing particular embodiments, and are not intended to limit the claimed invention, because the scope of the invention is limited only by the claims. Furthermore, unless otherwise required by context, singular terms shall include pluralities and plural terms shall include the singular.

Throughout the disclosure reference is made to electrostatic conductive fractions (ECF) and electrostatic non-conductive fractions (ENCF). The description is for the purposes of naming the two fractions obtained from the electrostatic separation. It will be appreciated that electrostatic conductivity of materials can vary and that, for example, materials that are separated into the electrostatic non-conductive fraction (ENCF) may exhibit some degree of conductivity, albeit a relatively lower conductivity than that of materials in the electrostatic conductive fraction (ECF). In addition, some electrostatic conductive materials may not be separated into the electrostatic conductive fraction (ECF) by the process and such material may be present in the electrostatic non-conductive fraction (ENCF).

Throughout this disclosure, unless specifically stated otherwise or the context requires otherwise, reference to a single step, composition of matter, group of steps or group of compositions of matter shall be taken to encompass one and a plurality (i.e., one or more) of those steps, compositions of matter, groups of steps or groups of compositions of matter. Thus, as used herein, the singular forms “a”, “an” and “the” include plural aspects unless the context clearly dictates otherwise. For example, reference to “a” includes a single as well as two or more; reference to “an” includes a single as well as two or more; reference to “the” includes a single as well as two or more and so forth.

The term “and/or”, e.g., “X and/or Y” shall be understood to mean either “X and Y” or “X or Y” and shall be taken to provide explicit support for both meanings or for either meaning.

Unless otherwise indicated, the terms “first” “second” etc. are used herein merely as labels, and are not intended to impose ordinal, positional, or hierarchical requirements on the items to which these terms refer. Moreover, reference to a “second” item does not require or preclude the existence of lower-numbered item (e.g., a “first” item) and/or a higher-numbered item (e.g., a “third” item).

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example and without limitation, two of item A, one of item B, and ten of item C; four of item B and seven of item C; or some other suitable combination.

As used herein, the term “about”, unless stated to the contrary, typically refers to +/−10%, for example +/−5%, of the designated value.

Throughout the present specification, various aspects and components of the invention can be presented in a range format. The range format is included for convenience and should not be interpreted as an inflexible limitation on the scope of the invention. Accordingly, the description of a range should be considered to have specifically disclosed all the possible sub-ranges as well as individual numerical values within that range, unless specifically indicated. For example, description of a range such as from 1 to 5 should be considered to have specifically disclosed sub-ranges such as from 1 to 3, from 1 to 4, from 1 to 5, from 2 to 4, from 2 to 5, from 3 to 5 etc., as well as individual and partial numbers within the recited range, for example, 1, 2, 3, 4,5, 5.5 and 6, unless where integers are required or implicit from context. This applies regardless of the breadth of the disclosed range. Where specific values are required, these will be indicated in the specification.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps. The phrase “consisting of” means the enumerated elements and no others.

### BRIEF DESCRIPTION OF DRAWINGS

Embodiments of the present disclosure are further described and illustrated as follows, by way of example only, with reference to the accompanying drawings in which:

FIG. 1 is a schematic cross-sectional view of an example crystalline silicon photovoltaic module;

FIG. 2 is a flow chart of an embodiment of a method according to the present disclosure;

FIG. 3 is a schematic of an embodiment of a system for performing a method according to the present disclosure;

FIG. 4 is a chart depicting the distribution of silver, copper and aluminum in the first and second fractions after separation with a method according to an embodiment of the present disclosure; and

FIG. 5 is a chart depicting the distribution of silicon in the first and second fractions after separation with a method according to an embodiment of the present disclosure.

### DESCRIPTION OF EMBODIMENTS

In the following description, reference is made to the accompanying drawings which form a part hereof, and which is shown, by way of illustration, several embodiments. It is understood that other embodiments may be utilized and structural changes may be made without departing from the scope of the present disclosure.

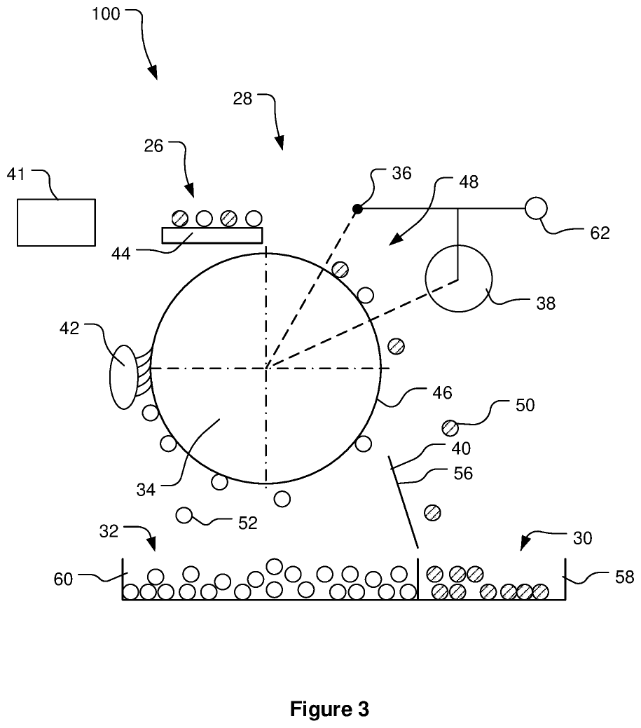

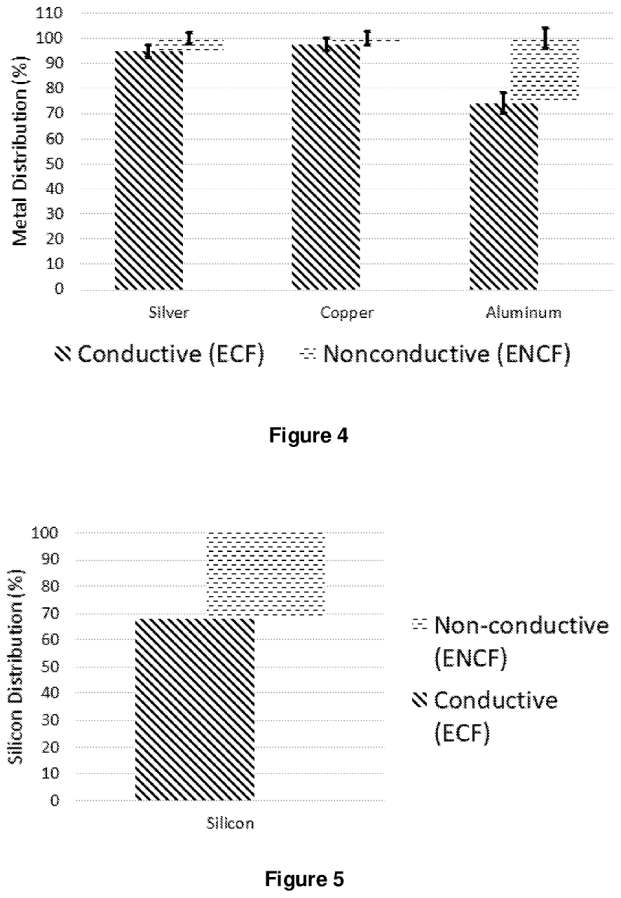

With reference to the Figures, and in particular FIGS. 2 and 3, the present disclosure provides a method 100 for recovering metallic materials 12 from crystalline silicon photovoltaic modules 10, 102.

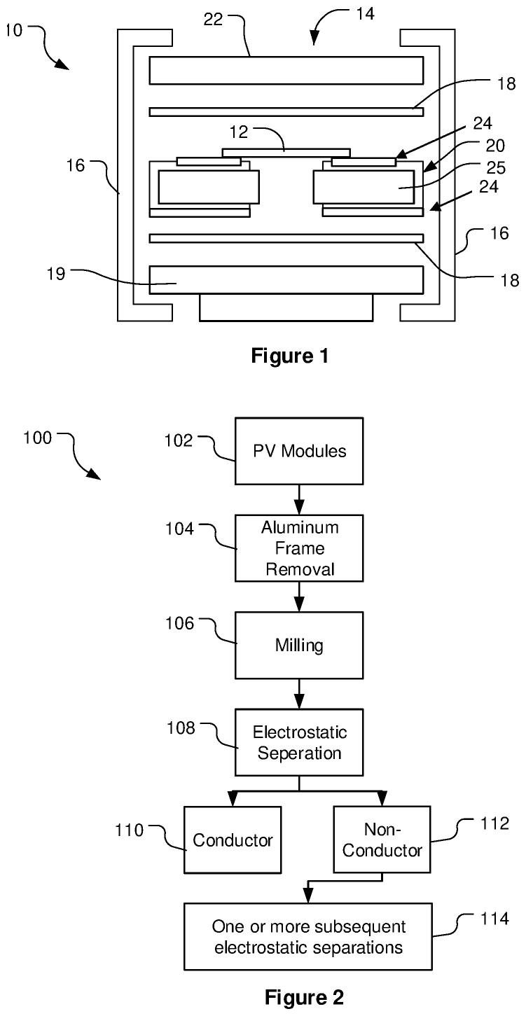

Crystalline silicon photovoltaic modules 10, for example as depicted at FIG. 1, typically comprise a photovoltaic sandwich structure 14, or laminate, which is surrounded by an aluminum frame 16 and attached to additional accessories such as the junction box (j-box) and associated cabling (not shown). Prior to undergoing electrostatic separation, the frame 16 and other accessories are manually or automatically removed 104 from the sandwich structure 14 and may be sent to secondary facilities for dedicated recycling. The remaining photovoltaic sandwich structure 14 (laminate) comprises EVA layers 18, a back sheet 19, solar cells 20, glass 22 and polymers 24, such as coating films.

The method 100 further comprises milling or shredding 106 the photovoltaic sandwich structures 14 to form photovoltaic sandwich structure particles 26. The sandwich structures may be shredded by a knife shredder (not shown), however it will be appreciated other methods may be used to otherwise break the photovoltaic sandwich structure 14 into smaller particles.

The formed particles 26 include particles of the various components forming the photovoltaic sandwich structure 14, including: metallic particles, silicon particles, glass particles and polymer particles. The sandwich structure 14 can be fed through the shredder until the formed particles 26 achieved a desired particle size and, optionally, particle size distribution. In the examples described below, the photovoltaic sandwich structures 14 were shredded until a particle size of less than 2 mm was achieved (i.e. the material passed through a 2 mm screen).

The shredded and screened photovoltaic sandwich structure particles 26 are then fed to an electrostatic separator 28 for electrostatic separation 108 into a first fraction (electrostatic conductive fraction (ECF)) 30 and a second fraction (electrostatic non-conductive fraction (ENCF)) 32.

The electrostatic separator 28 comprises a grounded rotating roll electrode 34, a corona electrode 36, an electrostatic electrode 38, a splitter 40, a humidity sensor 41, and a surface brush 42.

The shredded and screened photovoltaic sandwich structure particles 26 are fed in a monolayer, for example by a vibratory feeder 44, onto a surface 46 of the grounded rotating roll electrode 34. The particles 26 begin rotating along with the surface 46 of the rotating roll electrode 34. As the particles 26 are rotated through a field 48 of the corona electrode 36, the particles 26 undergo ionization and are charged. For conductive particles 50, 110 such as metals, this charge quickly dissipates to the grounded rotating roll electrode 34 while non-conductive particles 52, 112 are attracted to the grounded rotating roll electrode 34 due to Coulomb forces.

As the grounded rotating roll electrode 34 continues to rotate the particles 50, 52, as the charge attracting the conductive particles 50 dissipates and the conductive particles 50 are under the influence of centrifugal forces and the influence of the electrostatic electrode 38, the conductive particles 50 are thrown from the surface 46 of the grounded rotating roll electrode 34. The non-conductive particles 52 continue rotation with the surface 46 and, as the charge has taken longer to dissipate than for the conductive particles 50, the non-conductive particles 52 fall from the surface 46 of the grounded rotating roll electrode 34 at a further point in the rotation to the conductive particles 50.

To ensure the grounded rotating roll electrode 34 is substantially free of remaining non-conductive particles 52 prior to the electrostatic separator feed point 54, the surface brush 42 is provided for physically dislodging the non-conductive particles 52. The surface brush 42 may also act to dissipate the charge in the non-conductive particle 52 to assist in the particles 52 detaching from the surface 46.

The splitter 40 is further provided to separate the electrostatic conductive fraction (ECF) 30 from the electrostatic non-conductive fraction (ENCF) 32. The splitter 40 is sized, positioned and angled such that the desired conductive particle 50, as it is thrown from the grounded rotating roll electrode 34, passes over a leading edge 56 of the splitter 40 to be collected in a first collection receptacle 58. A second collection receptacle 60, separated from the first collection receptacle 58 by the splitter 40, is positioned for collection of the non-conductive particles 52 falling from the grounded rotating roll electrode 34.

In a preferred embodiment, to achieve the desired separation of the metallic material 12 from the glass 22 and polymer materials 24 of the photovoltaic module 10, the roll rotation speed of the grounded rotating roll electrode 34 is about 30 rpm, an electric potential difference 62 of the electrostatic separator 28 defined by a difference in electric potential between the corona and electrostatic electrodes 36, 38 and the grounded rotating roll electrode 34 is about 25 kV, and the splitter 40 is at about a 10° angle to the horizontal.

It has been found that humidity can significantly impact the degree of separation achieved by the described method 100. As such, the method 100 is performed at less than 45% humidity. This can be achieved by monitoring the humidity with one or more sensors to ensure the humidity is below 60%, and/or reducing the humidity to below this level through the employment of heaters and/or dehumidifiers (not shown).

While operating under the above conditions has been found to provide a good separation of metals from polymer and glass, to improve recovery of the metal 12 (i.e. reduce the fraction of the metals in the second fraction 32), at least a portion of the second fraction 32 further undergoes one or more subsequent electrostatic separations into the first and second fractions 30, 32. This may be in additional electrostatic separators positioned in series, and/or by being fed 114 into the same electrostatic separator 28 under which the initial separation 108 was conducted.

As the polymers 24 contained in the photovoltaic modules 10 are of little economic value and only partially recyclable, these materials are ideally separated into the second fraction (ENCF) 32. Similarly, there is currently low interest and economic value in recycling the glass material 22 as the alternative input material (silica sand) is cheap and readily available. As such, the glass material 22 is also preferably separated into the second fraction (ENCF) 32. Advantageously, the first fraction 30 recovered according to the above method 100 is substantially free of glass particles and contains less than about 5% by weight of total polymer particles. With reference to the examples below, in some embodiments the first fraction 30 contains less than about 2% by weight of polymer particles, and in a particularly advantageous embodiment the first fraction 30 is substantially free of polymer material or even no polymer material (0% by weight).

It will be understood that, if desired, the second fraction 32 may undergo further processing to recover the glass particles for further use.

The first fraction 30 produced by the method 100 described herein is primarily composed of silicon components 25 of the photovoltaic module 10 and the metallic components 12 of the photovoltaic modules (i.e. silver, copper, and aluminum). In particular, reference to the examples, it has been found that a mass concentration in the first fraction (ECF) 30 of about 68% for silicon, 94.7% (±2.39) for silver, 97.6% (±2.52) for copper and 74.3% (±3.99) for aluminum, was achieved.

The method 100 further recovers at least a portion of the silicon material 25 from the crystalline silicon photovoltaic modules 10 into the first fraction 30. For example, with reference to FIG. 5, approximately 68% by weight of silicon was recovered in the first fraction 30.

It will be understood that, if desired, the first fraction 30 may undergo further processing to recover one or more of the components (e.g. silver, copper, aluminum and/or silicon) for further use.

It will be appreciated that embodiments of methods according to the present disclosure can provide a simple, cost-effective and environmentally friendly method of recovering metallic material 12 from crystalline silicon photovoltaic modules 10. According to the described method 100, the high value materials of the photovoltaic module 10 can be concentrated into the first fraction 30 without the need of high amounts of energy or large infrastructure, allowing for a cheap, environmentally friendly way to deal with photovoltaic modules 10 at the end of their life cycle. By concentrating the valuable materials, which form approximately 2-3% by weight of the total module, the valuable materials can be more economically transported to downstream industry for further refinement.

It is to be appreciated that certain features that are, for clarity, described herein in the context of separate embodiments, may also be provided in combination in a single embodiment. Conversely, various features that are, for brevity, described in the context of a single embodiment, may also be provided separately or in any sub-combination.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

### EXAMPLES

The present disclosure is now described further in the following non-limiting examples.

### Materials and Methods—Mechanical Preparation

The aluminum frames and the junction boxes were removed from five crystalline silicon (c-Si) photovoltaic modules (PV), leaving the photovoltaic sandwich structure (PV laminate) 14. The PV laminate 14 was shredded 106 with a SM300 knives shredder (Retsch, Haan, Germany) until the output material could pass through a 2 mm screen. The shredded mix was sampled using a method commonly called “homogenous-quartered-standard-weight”: the output was divided into four (“quartered”), and then samples of equal weight (300 g in this case) were taken from each. Ten such samples were generated.

### Materials and Methods—Electrostatic Separation

Each of the ten samples was fed into an electrostatic separator 28—an MMPM-618C (Eriez, Erie, USA) high tension roll separator. The electric potential difference 62 between the wired electrodes 36, 38 (the corona and electrostatic electrodes) and the grounded rotating roll electrode 34 was 25 kV. The rotation speed of the grounded rotating roll electrode 34 was 30 revolutions per minute (RPM).

The corona electrode 36, electrostatic electrode 38, and the brush 42 were positioned as follows on an x, y plane relative to the center of the grounded rotating roll electrode 34 (which has a 12″ diameter):
corona electrode 36: x [90 mm; 240 mm], y [110 mm; 260 mm]
electrostatic electrode 38: x [255 mm, 450 mm], y [95 mm, 160 mm]
brush 56: x [−200 mm; −170 mm], y [−70 mm, 35 mm]

The humidity of the room was measured and kept below 45% using an Arsec250 dehumidifier (Arsec, Sao Paulo, Brazil). An external AK28 New hygrometer (AKSO, Sao Leopoldo, Brazil) was also used to measure the humidity.

Two receptacles or containers 58, 60 were placed underneath the separator 28 thus dividing the material separated by the electrostatic separator into a first fraction (electrostatic conductive fraction (ECF)) 30 and a second fraction (electrostatic non-conductive fraction (ENCF)) 32. Any material that remained adhered to the grounded rotating roll electrode 34 was dislodged by a brush 56 and collected in the non-conductive container 60.

### Results—Material Loss and Energy Consumption

The weight of the samples before separation and after four sequential separations was recorded. The electrostatic separation 108 yielded losses of 2.95 wt % on average. Losses may be due to dust during the processing. The mass loss and energy consumption across the 10 samples is summarised in Table 3 below.

The average mass distribution after the electrostatic separation had 3.34 wt % (±0.47) contained in the conductor fraction (ECF) 30, while the remaining 96.66 wt % (±0.47) in the nonconductor fraction (ENCF) 32. Noting that the laminate 14 represents roughly 82 wt % of the module 10 and accounting for the mass loss, the ECF 30 contained about 2.66 wt % of the total mass of the module 10.

TABLE 1
Material loss, energy consumed, and time consumed during electrostatic
separation process per kilogram of processed material.

| | Mass loss | Energy consumed |
|---|---|---|
| Sample | (wt. %) | (kWh/kg) |
| 1 | 5.86% | 0.718 |
| 2 | 5.20% | 1.101 |
| 3 | 3.52% | 1.424 |
| 4 | 2.54% | 1.324 |
| 5 | 3.35% | 1.302 |
| 6 | 2.54% | 1.024 |
| 7 | 3.35% | 1.034 |
| 8 | 1.65% | 1.007 |
| 9 | 0.04% | 1.019 |
| 10 | 1.40% | 1.013 |
| Average | 2.95% | 1.097 |
| Standard Deviation | 1.73% | 0.204 |

### Results—Metal Separation: Silver, Copper and Aluminum

Five of the samples were analyzed to assess the distribution of the metals silver, copper and aluminum between the first and second fractions (ECF and ENCF) 30, 32.

To evaluate the metal distribution (silver, copper and aluminum) in each fraction 30, 32, the outputs (i.e., ECF and ENCF) 30, 32 were digested in nitric acid (65% concentration), to leach silver and copper and then hydrochloric acid (38% concentration), to leach aluminum. Each digestion was conducted at room temperature, had a 10:1 liquid-solid ratio (to ensure complete digestion) and was magnetically stirred.

After each digestion, the solid fraction was separated by filtration, then rinsed and dried. The solid fraction was reserved.

The solutions analyzed by inductively coupled plasma optical emission spectroscopy (ICP-OES) to determine the amount of silver, copper and aluminum in each sample. The equipment used was a 5110 ICP-OES (Agilent Technologies, California, USA).

The results of the analysis are shown in FIG. 5, which shows a mass concentration of 94.7% (±2.39) for silver, 97.6% (±2.52) for copper and 74.3% (±3.99) for aluminum, all in the ECF 30. That is, the method 100 demonstrated a high recovery of valuable metals in the first fraction (ECF) 30 with only small losses of silver and copper to the second fraction (ENCF) 32.

Results—Polymer Separation

The polymers contained in PV modules 10 are of little economic value and only partially recyclable. Therefore, these materials would ideally be separated into the second fraction (ENCF) 32.

Thus, the separated fractions (ECF and ENCF) 30, 32 were assessed for polymer distribution. The reserved solid from the metal separation analysis was placed in a furnace under atmospheric conditions (500° C. for 5 hours). The gravimetric mass difference before and after the furnace is the mass of the polymeric fraction contained in each fraction (ECF vs. ENCF) 30, 32.

The results of the analysis are shown in Table 4 below, which shows a high selectivity of the method for separating the polymer into the second fraction (ENCF) 32. Indeed, the analysis demonstrated that when applying the method 100, only about 2 wt %, on average, of the polymers were contained in the ECF 30 after the proposed process. Sample 3 has achieved 100% separation, leaving all polymeric matter in the ENCF 32.

TABLE 2
Polymer mass distribution after electrostatic separation.

| Sample | ECF (wt %) | ENCF (wt %) |
|---|---|---|
| 1 | 2.40 | 97.60 |
| 2 | 3.43 | 96.57 |
| 3 | 0.00 | 100.00 |
| 4 | 1.14 | 98.86 |
| 5 | 1.64 | 98.36 |
| Average | 1.72 | 98.28 |
| Standard Deviation | 1.29 | 1.29 |

### Results-Silicon and Glass Separation

Samples were further analysed to assess the distribution of silicon and glass in the first and second fractions (ECF and ENCF) 30, 32. Results for the effect of the electrostatic separation 108 on the silicon and glass are measured by analyzing the crystallinity of the remaining sample after removing all metals and polymers as described in the preceding results summaries.

Samples were ground and analyzed by X-ray diffraction (XRD) using a Siemens (Bruker AXS, Germany) D-5000 diffractometer. Rietveld Quantitative Phase Analysis (RQPA) was used to measure the crystallinity of the samples by adding an internal standard of hexagonal (P63 mc) ZnO. Material categorized as amorphous phase or quartz phase were assumed to be glass, while material categorized as crystalline was assumed to be silicon.

The results of the analysis are shown in FIG. 5 and Table 3 below. Table 5 shows the crystallinity of the ECF 30 and ENCF 32, where the glass is considered to be the non-crystalline (amorphous) fraction plus any identified quartz fraction. Under these assumptions, the ECF had only silicon (no glass) in both samples, while the ENCF 32 had both silicon and glass. The distribution of silicon in Sample 9 was 67.54% in the ECF 30 and 32.46% in the ENCF 32. Sample 10 yielded similar result, with 68.28% of the silicon in the ECF 30 and 31.72% in the ENCF 32. FIG. 5 provides a visual representation of the silicon distribution taking the average of these two samples.

TABLE 3
Crystallinity of materials in the conductive (ECF) 30
and non-conductive fractions (ENCF) 32 after electrostatic
separation. Samples are the remainder of the leaching
and thermal degradation process done prior.

Crystallinity (wt %)

| Sample | ECF | ENCF |
|---|---|---|
| 9 | 100 | 2.08 |
| 10 | 100 | 1.76 |
| Average | 100 | 1.92 |

### Reference Numerals

10: Photovoltaic module
12: Metallic materials
14: Photovoltaic sandwich structure
16: Aluminium frame
18: EVA layers
19: Back sheet
20: Solar cells
22: Glass
24: Polymers
25: Silicon components
26: Formed particles
28: Electrostatic separator
30: Electrostatic conductive fraction (ECF)
32: Electrostatic non-conductive fraction (ENCF)
34: Grounded rotating roll electrode
36: Corona electrode
38: Electrostatic electrode
40: Splitter
41: Humidity sensor
42: Surface brush
44: Vibratory feeder
46: Surface of the grounded rotating roll electrode
48: Field of the corona electrode
50: Conductive particles
52: Non-conductive particles
54: Separator feed point
56: Leading edge of the splitter
58: First collection receptacle
60: Second collection receptacle
62: Electric potential difference
100: Method for recovering metallic materials
102: Photovoltaic modules
104: Aluminium frame removal
106: Milling or shredding the photovoltaic sandwich structures
108: Electrostatic separation
110: Conductive particles
112: Non-conductive particles

1. A method for recovering metallic materials from crystalline silicon photovoltaic modules, the method comprising:
removing aluminum frames and junction boxes from the photovoltaic modules to provide photovoltaic sandwich structures;
shredding the photovoltaic sandwich structures to form photovoltaic sandwich structure particles, the photovoltaic sandwich structure particles comprising: metallic particles, silicon particles, glass particles and polymer particles;
electrostatically separating the photovoltaic sandwich structure particles into a first fraction and a second fraction with an electrostatic separator, the electrostatic separator comprising:
a grounded rotating roll electrode rotating at a roll rotation speed about a substantially horizontal longitudinal roll electrode axis;
a corona electrode and an electrostatic electrode, wherein a difference in electric potential between the corona and electrostatic electrodes and the roll electrode define an electric potential difference of the electrostatic separator;
a splitter sized, positioned and angled for splitting the first and second fractions;
a surface brush for dislodging second fraction particles from the surface of the grounded rotating roll electrode; and
a humidity sensor for measuring humidity, wherein electrostatically separating the photovoltaic sandwich structure particles is conducted at a humidity of less than about 60%; and
feeding at least a portion of the second fraction to an electrostatic separator for one or more subsequent electrostatic separations into the first and second fractions;
wherein the roll rotation speed of the grounded rotating roll electrode, the electric potential difference and the splitter size, position are angle are selected such that the first fraction comprises less than 5 percent by weight of total polymer particles and is substantially free of glass particles.

2. The method process according to claim 1, wherein shredding the photovoltaic sandwich structures comprises sieving the photovoltaic sandwich structure particles thereby to define a maximum particle size of the photovoltaic sandwich particles for electrostatic separation.

3. The method according to claim 2, wherein the maximum particle size is less than 10 mm.

4. The method according to claim 3, wherein the maximum particle size is less than 2 mm.

5. The method according to claim 1, wherein one or more of the subsequent electrostatic separations are performed by one or more additional electrostatic separators in series.

6. The method according to claim 1, wherein one or more of the subsequent electrostatic separations are performed by an electrostatic separator that performed one or more preceding separations.

7. The method according to claim 1, wherein the second fraction undergoes at least 3 subsequent electrostatic separations.

8. The method according to claim 1, wherein the roll rotation speed of the grounded rotating roll electrode is about 30 rpm.

9. The method according to claim 1, wherein the electric potential difference of the electrostatic separator is about 25 kV.

10. The method according to claim 1, wherein the splitter is at about a 10° angle to the vertical.

11. The method according to any one of the preceding claim 1, wherein the metal particles comprise silver particles, copper particles, and aluminum particles.

12. The method according to claim 11, wherein the roll rotation speed of the grounded rotating roll electrode, the electric potential difference and the splitter size, position are angle are selected such that the first fraction comprises greater than 90 percent by weight of total silver particles.

13. The method according to claim 11, wherein the roll rotation speed of the grounded rotating roll electrode, the electric potential difference and the splitter size, position and angle are selected such that the first fraction comprises greater than 95 percent by weight of total silver particles.

14. The method according to claim 11, wherein the roll rotation speed of the grounded rotating roll electrode, the electric potential difference and the splitter size, position and angle are selected such that the first fraction comprises greater than 70 percent by weight of total aluminum particles.

15. The method according to claim 1, further comprising maintaining the humidity below a predetermined threshold value.

16. The method according to claim 15, wherein for maintaining the humidity at below a predetermined threshold value comprises reducing humidity with a heater and/or a dehumidifier.

17. The method according to claim 1, further comprising feeding a monolayer of the photovoltaic sandwich structure particles to the electrostatic separator.

18. The method according to claim 17, wherein the monolayer is formed with a vibratory feeder.

19. A method for recovering metallic materials from crystalline silicon photovoltaic modules, the method comprising:
removing aluminum frames and junction boxes from the photovoltaic modules to provide photovoltaic sandwich structures;
shredding the photovoltaic sandwich structures to form photovoltaic sandwich structure particles, the photovoltaic sandwich structure particles comprising: metallic particles, silicon particles, glass particles and polymer particles;
sieving the photovoltaic sandwich structure particles to provide feed photovoltaic sandwich structure particles having a predefined maximum particle size;
feeding a monolayer of the feed photovoltaic sandwich structure particles to an electrostatic separator, and electrostatically separating the photovoltaic sandwich structure particles into a first fraction and a second fraction with the electrostatic separator, the electrostatic separator comprising:
a grounded rotating roll electrode rotating at about 30 rpm about a substantially horizontal longitudinal roll electrode axis;
a corona electrode and an electrostatic electrode, wherein a difference in electric potential between the corona and electrostatic electrodes and the roll electrode define an electric potential difference of the electrostatic separator of about 25 kV;
a splitter sized, positioned and angled for splitting the first and second fractions;
a surface brush for dislodging second fraction particles from the surface of the grounded rotating roll electrode; and
a humidity sensor for measuring humidity, wherein electrostatically separating the photovoltaic sandwich structure particles is conducted at a humidity of less than about 60%; and
feeding at least a portion of the second fraction to an electrostatic separator for one or more subsequent electrostatic separations into the first and second fractions;
wherein the first fraction comprises less than 5 percent by weight of total polymer particles and is substantially free of glass particles.
